(19) United States
(12) Patent Application Publication
(10) Pub. No.: US 2016/0141546 A1
(43) Pub. Date: May 19, 2016

(54) DISPLAY PANEL

(71) Applicant: Innolux Corporation, Miao-Li County (TW)

(72) Inventors: Jin-Ju Lin, Miao-Li County (TW); Neng-Jung You, Miao-Li County (TW); Wei-Chih Yang, Miao-Li County (TW); Wei-Chieh Teng, Miao-Li County (TW); Yi-Hong Lin, Miao-Li County (TW)

(21) Appl. No.: 14/943,160

(22) Filed: Nov. 17, 2015

(30) Foreign Application Priority Data
Nov. 18, 2014 (TW) 103139879

(51) Int. Cl. H01L 51/52; H01L 27/32

(52) U.S. Cl. CPC H01L 51/5237; H01L 51/5203; H01L 27/3244; H01L 2251/303

(57) ABSTRACT

An organic light emitting diode (OLED) display device and a manufacturing method thereof are provided. The OLED display device includes a first substrate, an organic light emitting element disposed on the first substrate, a first inorganic layer, and a second inorganic layer. The organic light emitting element includes a first electrode disposed on the first substrate, an organic light emitting layer disposed on the first electrode, and a second electrode disposed on the organic light emitting layer. The first inorganic layer covers the organic light emitting element, wherein the first inorganic layer has a first thickness. The second inorganic layer covers the first inorganic layer and covers the organic light emitting element, wherein the second inorganic layer has a second thickness larger than the first thickness, and the second inorganic layer has a consistency less than the consistency of the first inorganic layer.

This application claims the benefit of Taiwan application Serial No. 103139879, filed Nov. 18, 2014, the subject matter of which is incorporated herein by reference.

### BACKGROUND OF THE INVENTION

1. Field of the Invention

The present disclosure is related in general to a display device and the manufacturing method thereof, and particularly to an organic light emitting diode (OLED) display device.

2. Description of the Related Art

OLED displays have advantages of thinness, active light-emitting without backlight sources, no viewing angle restriction, and etc.

Emission layers in OLED display panels are mostly manufactured by an evaporating process and are usually very sensitive to water and oxygen, and accordingly the display panels may deteriorate due to the penetration of water and oxygen, thereby influencing the properties of the displays. Therefore, researchers have been working on providing OLED display panels having excellent resistance to water and oxygen as well as superior display performance.

### SUMMARY OF THE INVENTION

The embodiments of the present disclosure are directed to an OLED display device. In the display device of the embodiments, the first inorganic layer having a higher consistency and a smaller thickness in combination of the second inorganic layer having a less consistency yet a larger thickness can effectively achieve an excellent resistance to water and oxygen and can be provided with advantages of shortening the time of the manufacturing process thereof.

According to an embodiment of the present disclosure, an OLED display device is provided. The OLED display device includes a first substrate, an organic light emitting element, a first inorganic layer, and a second inorganic layer. The organic light emitting element is disposed on the first substrate and includes a first electrode, an organic light emitting layer, and a second electrode. The first electrode is disposed on the first substrate, the organic light emitting layer is disposed on the first electrode, and the second electrode is disposed on the organic light emitting layer. The first inorganic layer covers the organic light emitting element, wherein the first inorganic layer has a first thickness. The second inorganic layer covers the first inorganic layer and further covers the organic light emitting element, wherein the second inorganic layer has a second thickness larger than the first thickness, and the second inorganic layer has a consistency equal to or less than that of the first inorganic layer.

According to an embodiment of the present disclosure, a manufacturing method of an OLED display device is provided. The manufacturing method of the OLED display device includes the following steps: providing a first substrate; disposing an organic light emitting element on the first substrate, including: disposing a first electrode on the first substrate; disposing an organic light emitting layer on the first electrode; and disposing a second electrode on the organic light emitting layer; forming a first inorganic layer on the second electrode by a chemical deposition process, wherein the first inorganic layer has a first thickness; and forming a second inorganic layer covering the first inorganic layer and the organic light emitting element by a physical deposition process, wherein the second inorganic layer has a second thickness larger than the first thickness.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a schematic diagram of an OLED display device according to an embodiment of the present disclosure; and

FIG. 2 shows a schematic diagram of an OLED display device according to another embodiment of the present disclosure.

### DETAILED DESCRIPTION OF THE INVENTION

According to the embodiments of the present disclosure, a display panel is provided. In the embodiments, in the display device of the embodiments, the first inorganic layer having a higher consistency and a thinner thickness in combination of the second inorganic layer having a lower consistency yet a thicker thickness can effectively achieve an excellent resistance to water and oxygen and can be provided with advantages of shortening the time of the manufacturing process thereof. The embodiments are described in details with reference to the accompanying drawings. However, the embodiments are for exemplification only, not for limiting the scope of protection of the disclosure. Besides, some of the secondary elements are omitted in the drawings accompanying the following embodiments to highlight the technical features of the invention.

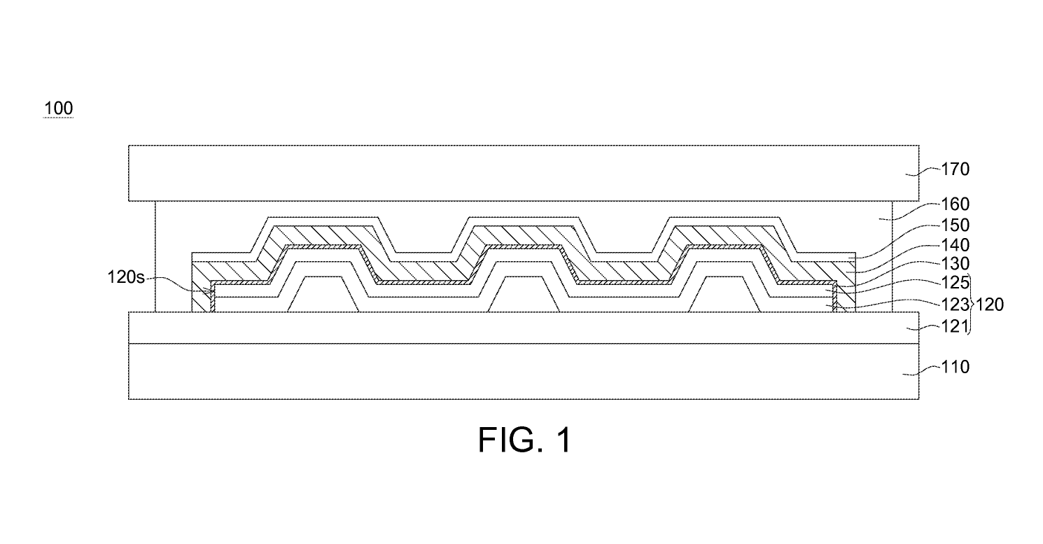

FIG. 1 shows a schematic diagram of an organic light emitting diode (OLED) display device 100 according to an embodiment of the present disclosure. As shown in FIG. 1, the OLED display device 100 includes a first substrate 110, an organic light emitting element 120, a first inorganic layer 130, and a second inorganic layer 140. The organic light emitting element 120 is disposed on the first substrate 110 and includes a first electrode 121, an organic light emitting layer 123, and a second electrode 125. The first electrode 121 is disposed on the first substrate 110, the organic light emitting layer 123 is disposed on the first electrode 121, and the second electrode 125 is disposed on the organic light emitting layer 123. The first inorganic layer 130 covers the organic light emitting element 120, and the first inorganic layer 130 has a first thickness T1. The second inorganic layer 140 covers the first inorganic layer 130 and further covers the organic light emitting element 120, and the second inorganic layer 140 has a second thickness T2 larger than the first thickness T1. The second inorganic layer 140 has a consistency equal to or less than that of the first inorganic layer 130.

The first inorganic layer 130 having a higher consistency but a smaller thickness in combination of the second inorganic layer 140 having a less consistency yet a larger thickness can effectively achieve an excellent resistance to water and oxygen. Moreover, since the second inorganic layer 140 having a less consistency requires a shorter manufacturing time, and thus the time required for the manufacturing process of the whole water-oxygen resistance structure, that is, the combination of the first inorganic layer 130 and the second inorganic layer 140, can be further reduced.

According to the embodiments of the present disclosure, the consistency refers to the ratio of volume of atoms to the volume of the cell. The formula for calculating the consistency is as follows: K=nv/V, wherein n indicates the number of atoms in a cell, v indicates the volume of one atom, and V indicates the volume of the cell (V=a³, wherein a indicates the lattice constant). For example, in a BCC (body-centered cubic lattice) cell, the number of atoms in a cell is 2, the atomic radius is (√¾)*a, the volume of a cell is a³, and from which the consistency is calculated as K=0.68.

In the embodiment, when the first inorganic layer 130 and the second inorganic layer 140 are etched by an etching agent, an etching rate of the first inorganic layer 130 is smaller than an etching rate of the second inorganic layer 140. In other words, the first inorganic layer having a higher consistency is less easily etched. In the embodiment, the etching agent is not limited to a dry etching process or a wet etching process. For example, after the first inorganic layer 130 and the second inorganic layer 140 are both immersed in an acidic solution for a certain period of time, the second inorganic layer 140 would have a rougher surface while the first inorganic layer 130 has a less rough surface. According to the embodiments of the present disclosure, the etching agent may be such as a mixed solution of nitric acid and hydrofluoric acid.

In an embodiment, the first inorganic layer 130 and the second inorganic layer 140 are formed of the same material, such that the adhesion between the two layers is improved. In the embodiment, the first inorganic layer 130 and the second inorganic layer 140 may respectively include metal, oxide, carbide, nitride, oxynitride, carbon nitride, and/or carbon oxide. For example, metal may include Al, Mg, Ti, Zn, W, Si, and/or Sn; oxide may include Al₂O₃, SiO₂, TiO₂, ZrO₂, MgO, HfO₂, and/or Ta₂O₅; carbide may include SiC, WC and/or TiC; nitride may include TiN, TiAln, and/or SiN; oxynitride may include SiON and/or AION; carbon nitride may include SiNC; carbon oxide may include SiOC. However, the selections of the materials of the first inorganic layer 130 and the second inorganic layer 140 may be same or different from each other, may depend on actual needs, and are not limited to the above-mentioned.

In the embodiment, the first inorganic layer 130 is formed by such as a chemical vapor deposition process, and the second inorganic layer 140 is formed by such as a physical deposition process.

In the embodiment, the first inorganic layer 130 is such as formed on the second electrode 125 and is in direct contact with the second electrode 125, and the second inorganic layer 140 is such as formed on the first inorganic layer 130 and is in direct contact with the first inorganic layer 130. When the first inorganic layer 130 and the second inorganic layer 140 are formed of the same material, the first inorganic layer 130 may be treated as a seed layer of the second inorganic layer 140, such that the as-formed second inorganic layer 140 has an enhanced consistency.

In the embodiment, the first inorganic layer 130 and the second inorganic layer 140 cover the side 120s of the organic light emitting element 120, as shown in FIG. 1, for forming a complete protection.

In an embodiment, the first thickness T1 of the first inorganic layer 130 is such as 100-500 Å and the second thickness T2 of the second inorganic layer 140 is such as 4000-5000 Å. In another embodiment, the first thickness T1 of the first inorganic layer 130 is such as 100-200 Å and the second thickness T2 of the second inorganic layer 140 is such as 4000-5000 Å.

In the embodiment, at least one of the first electrode 121 and the second electrode 125 may be a transparent electrode. For example, when the first electrode 121 is a transparent electrode, the OLED display device 100 is a bottom emission display device, and when the second electrode 125 is a transparent electrode, the OLED display device 100 is a top emission display device.

In the embodiment, as shown in FIG. 1, the OLED display device 100 may further include a moisture absorption material layer 150. The moisture absorption material layer 150 is disposed on the second inorganic layer 140. The moisture absorption material layer 150 may absorb a portion of the moisture from surroundings for providing a better resistance to water and oxygen. In an embodiment, as shown in FIG. 1, the moisture absorption material layer 150 cover the upper portion of the second inorganic layer 140. In an alternative embodiment, the moisture absorption material layer 150 fully covers the second inorganic layer 140 for providing a better resistance to water and oxygen.

In the embodiment, as shown in FIG. 1, the OLED display device 100 may further include an encapsulation layer 160. The encapsulation layer 160 covers the second inorganic layer 140 and the moisture absorption material layer 150.

In the embodiment, as shown in FIG. 1, the OLED display device 100 may further include a second substrate 170. The organic light emitting element 120, the first inorganic layer 130, and the second inorganic layer 140 are disposed between the first substrate 110 and the second substrate 170.

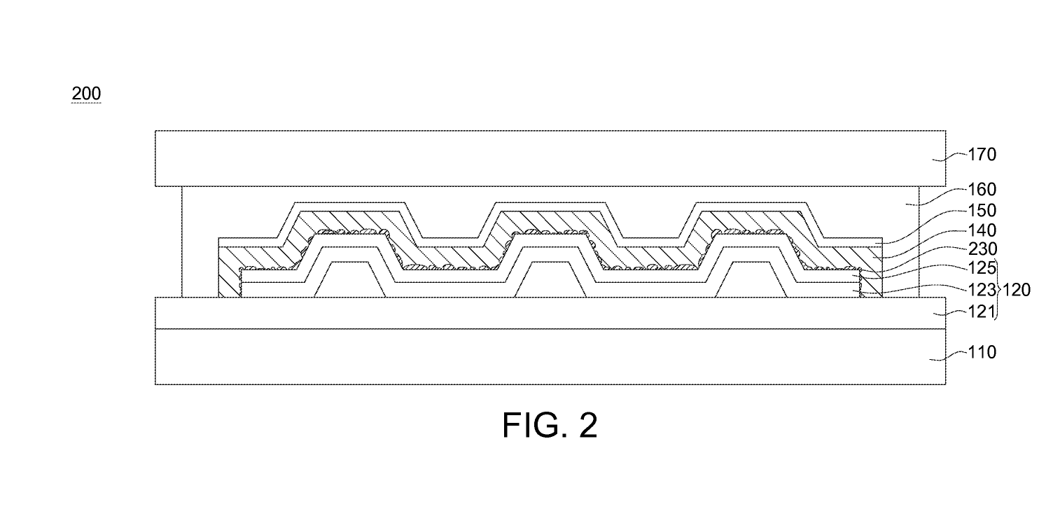

FIG. 2 shows a schematic diagram of an OLED display device 200 according to another embodiment of the present disclosure. The elements in the present embodiment sharing similar or the same labels with those in the previous embodiment are similar or the same elements, and the description of which is omitted.

As shown in FIG. 2, in the OLED display device 200, the first inorganic layer 230 has an island-shaped structure. In the embodiment, the first inorganic layer 230 is formed by such as a chemical deposition process, and the thickness of the deposition may be controlled at below 100 Å for forming the first inorganic layer 230 having the island-shaped structure. As such, the island-shaped structure of the first inorganic layer 230 may have a function of similar to that of a seed layer, and the irregular profile of the island-shaped structure is advantageous to the growth of the second inorganic layer 140 when the second inorganic layer 140 is formed on the first inorganic layer 230 by a PVD process, such that the quality of film formation of the second inorganic layer 140 is improved, the manufacturing time thereof is further reduced, and the production efficiency is increased.

According to the embodiments of the present disclosure, a manufacturing method of an OLED display device is provided. Please refer to FIG. 1.

First, the first substrate 110 is provided. Next, the organic light emitting element 120 is disposed on the first substrate 110. The manufacturing method of the organic light emitting element 120 includes such as disposed the first electrode 121 on the first substrate, disposing the organic light emitting layer 123 on the first electrode 121, and disposing the second electrode 125 on the organic light emitting layer 123.

Next, referring to FIG. 1, the first inorganic layer 130 is formed on the second electrode 125. In the embodiment, the first inorganic layer 130, for example, covers the organic light emitting element 120. The first inorganic layer 130 has a first thickness T1 and is made by a chemical deposition process. The chemical deposition process may include a chemical vapor deposition (CVD) process, an atomic layer deposition (ALD) process, or an atomic layer epitaxial (ALE) growth process.

Next, referring to FIG. 1, the second inorganic layer 140 is formed on the first inorganic layer 130, and the second inorganic layer 140 together with the first inorganic layer 130 fully cover the organic light emitting element 120. The second inorganic layer 140 has a second thickness T2 larger than the first thickness T1, and the second inorganic layer 140 is formed by a physical deposition process. In the embodiment, the physical deposition process may include a physical vapor deposition (PVD) process.

In the embodiment, the second inorganic layer 140 is formed on the first inorganic layer 130 and is in direct contact with the first inorganic layer 130.

In the embodiment, the consistency of the second inorganic layer 140 is less than the consistency of the first inorganic layer 130.

Specifically speaking, in the embodiment, the first inorganic layer 130 formed by a chemical deposition process has a higher consistency, a better crystalline structure, and a better morphology, which may be treated as a seed layer for forming the second inorganic layer 140. As such, despite that the second inorganic layer 140 is formed by a physical deposition process, the second inorganic layer 140 formed on the first inorganic layer 130 may have a higher consistency and a better crystalline structure as well as a better morphology compared to a conventional inorganic film formed by a physical deposition process. Moreover, when the same thicknesses are desired, the time required for a physical deposition process is a lot shorter than that required for a chemical deposition process, such that the whole manufacturing time for forming the water-oxygen resistance structure is greatly shortened.

In comparison, the manufacture of a thick and consistent inorganic water-oxygen resistance layer formed only by a CVD process or an epitaxial growth process is very time consuming, thereby disadvantageous to the manufacturing time and cost.

According to the embodiments of the present disclosure, an uniform oxide or nitride layer (e.g. the first inorganic layer 130) having thinner thickness but higher consistency is deposited by a chemical deposition process, followed by the formation of an oxide or nitride layer (e.g. the second inorganic layer 140) having larger thickness deposited on the as-formed thin layer by a physical deposition process, such that the first inorganic layer 130 in combination with the second inorganic layer 140 form a passivation layer providing with resistance to water and oxygen. Such manufacturing method is somehow similar to the crystal growth from seeds; that is, a consistent thin layer, which may be treated as a seed layer, having nice morphology is formed slowly by a chemical process, and then oxide or nitride is grown quickly by a physical process to be stacked on the seed layer/thin layer. The oxide or nitride formed by such physical deposition process may be grown and retaining and continuing the uniform morphology of the thin layer, and the passivation layer having consistent morphology may be formed by a quick manufacturing process.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An organic light emitting diode (OLED) display device, comprising:
a first substrate;
an organic light emitting element disposed on the first substrate, the organic light emitting element comprising:
a first electrode disposed on the first substrate;
an organic light emitting layer disposed on the first electrode; and
a second electrode disposed on the organic light emitting layer;
a first inorganic layer covering the organic light emitting element, wherein the first inorganic layer has a first thickness; and
a second inorganic layer covering the first inorganic layer, wherein the second inorganic layer has a second thickness larger than the first thickness, and a consistency of the second inorganic layer is equal to or less than a consistency of the first inorganic layer.

2. The OLED display device according to claim 1, wherein an etching rate of the first inorganic layer is smaller than an etching rate of the second inorganic layer when the first inorganic layer and the second inorganic layer are etched by an etching agent.

3. The OLED display device according to claim 1, wherein the first inorganic layer is formed by a chemical deposition process, and the second inorganic layer is formed by a physical deposition process.

4. The OLED display device according to claim 3, wherein the first thickness is 100-500 Å and the second thickness is 4000-5000 Å.

5. The OLED display device according to claim 4, wherein the first thickness is 100-200 Å.

6. The OLED display device according to claim 5, wherein the first inorganic layer and the second inorganic layer respectively comprise oxide or nitride.

7. The OLED display device according to claim 1, further comprising:
a moisture absorption material layer disposed on the second inorganic layer; and
an encapsulation layer covering the second inorganic layer and the moisture absorption material layer.

8. A manufacturing method of an OLED display device, comprising:
providing a first substrate;
disposing an organic light emitting element on the first substrate, comprising:
disposing a first electrode on the first substrate;
disposing an organic light emitting layer on the first electrode; and
disposing a second electrode on the organic light emitting layer;
forming a first inorganic layer on the second electrode by a chemical deposition process, wherein the first inorganic layer has a first thickness; and
forming a second inorganic layer covering the first inorganic layer and the organic light emitting element by a physical deposition process, wherein the second inorganic layer has a second thickness larger than the first thickness.

9. The manufacturing method of an OLED display device according to claim 8, wherein the second inorganic layer is formed on the first inorganic layer and is in direct contact with the first inorganic layer.

10. The manufacturing method of an OLED display device according to claim 8, wherein a consistency of the second inorganic layer is less than a consistency of the first inorganic layer.
